(19) United States
(12) Patent Application Publication
(10) Pub. No.: US 2026/0179683 A1
(43) Pub. Date: Jun. 25, 2026

(54) STOCHASTIC MATRIX-VECTOR MULTIPLY-ACCUMULATE OPERATION SYSTEM AND OPERATION METHOD THEREOF

(71) Applicant: PEKING UNIVERSITY, Beijing (CN)

(72) Inventors: Yimao CAI, Beijing (CN); Zongwei WANG, Beijing (CN); Haoran WANG, Beijing (CN)

(21) Appl. No.: 19/124,308

(22) PCT Filed: Oct. 19, 2023
(86) PCT No.: PCT/CN2023/125376

§ 371 Date: Apr. 25, 2025

(30) Foreign Application Priority Data
Apr. 28, 2023 (CN) 202310477985.6

(51) Int. Cl. G11C 13/00

(52) U.S. Cl. CPC G11C 13/0004

(57) ABSTRACT

Disclosed are a stochastic matrix-vector multiply-accumulate operation system and an operation method thereof. The operation system includes an input bit-stream generator, a weight bit-stream generator and a memory array. The input bit-stream generator generates a pulse sequence representing a corresponding input stochastic bit-stream according to respective preset input values of a preset input vector, the weight bit-stream generator generates a pulse sequence representing a corresponding weight stochastic bit-stream according to respective preset weight values of a preset weight matrix, and the pulse sequence representing the input stochastic bit-stream and the pulse sequence representing the weight stochastic bit-stream are applied to a word line and a bit line of the memory array respectively. In addition, a result multiply-accumulating between the input stochastic bit-stream and the weight stochastic bit-stream of each memory device of the memory array is stored as a conductance value of the corresponding memory device.

The present disclosure claims priority to a Chinese patent application No. 202310477985.6 filed on Sep. 8, 2023, entitled “STOCHASTIC MATRIX-VECTOR MULTIPLY-ACCUMULATE OPERATION SYSTEM AND OPERATION METHOD THEREOF.”

### TECHNICAL FIELD

The present disclosure relates to the technical field of operation circuit design, and more specifically, to a stochastic matrix-vector multiply-accumulate operation system and an operation method thereof.

### BACKGROUND

In recent years, although the number of devices integrated per unit area of CMOS integrated circuits keeps increasing, its scaling has slowed down as the size of transistors approaches the physical limit, heralding the end of Moore's Law. On the other hand, affected by process fluctuations and device variations, circuit reliability decreases and the operating voltage cannot be scaled down. Therefore, due to power consumption limitations, in an integrated circuit with multiple cores, only a small portion can work simultaneously, leading to the “dark silicon” dilemma.

Facing the above challenges, the architecture and circuit design can be innovated through process optimization, novel devices, or new computing paradigms, in order to meet the power consumption, reliability, and circuit overhead requirements for future technologies.

As a unary-encoding algorithm, stochastic computing is a revolutionary computing paradigm in terms of data encoding. Stochastic computing encodes “0” and “1” bits, which are given the same weight, into a bit stream, where the encoded value is determined by the proportion of “1” in the bit-stream. Compared with traditional binary computing, stochastic computing has the advantages of high fault tolerance, simple circuit logic, low hardware overhead, and low power consumption.

In view of the above unique advantages, stochastic computing has been widely used in many fields, such as image processing, image edge detection, Gamma correction, etc., and complex functions can be realized through a simple circuit structure. Neural networks are widely used in the fields of artificial intelligence and machine learning, such as feature extraction, classification, system control, etc. Its nonlinear characteristics, flexible configuration and adaptive capabilities provide great convenience for applications such as machine learning. Combined with the strong fault tolerance of artificial neural networks, stochastic computing can also be applied to neural networks. Currently, stochastic computing has been applied in convolutional neural network (CNN) and binary neural network calculations.

The basic computing unit of a stochastic computing neural network consists of a stochastic bit-stream generator array and a stochastic computing circuit. The stochastic computing circuit implements the functions of neurons, including multipliers, adders and activation function circuits.

The stochastic computing unit circuit based on CMOS has the problems of high latency, complex circuit structure and poor parallelism. At present, the implementation methods based on emerging nonvolatile memory devices can be divided into two categories. The first is a hybrid implementation method. For example, after the stochastic bit-stream is generated in the resistive random-access memory array, it is transmitted to a CMOS logic circuit for stochastic computing. However, in this method, the data moves frequently between the memory and the processor, the intermediate conversion circuit is complex, and the circuit overhead is large, which is a disadvantage for large-scale parallel computation, resulting in high latency and high power consumption. The second is a method based on in-memory processing. At present, unipolar and bipolar multiplication operations have been realized based on emerging nonvolatile memory devices. This method does not require additional circuits, can further reduce power consumption, and improve fault tolerance. However, its key problem is that the number of operation cycles is large and the operation is complex, which put forward higher demands for device reliability.

Based on the above technical problems, there is an urgent need for a method to implement stochastic matrix-vector multiply-accumulate operations that is simple to operate, has low power consumption, and has high parallelism.

### SUMMARY

In view of the above problems, the purpose of the present disclosure is to provide a stochastic matrix-vector multiply-accumulate operation system and the operation method thereof to solve the problems of low operation speed, low degree of parallelism and high hardware overhead of traditional multiply-accumulate computing units in stochastic computing.

The stochastic matrix-vector multiply-accumulate operation system provided by the present disclosure includes an input bit-stream generator, a weight bit-stream generator and a memory array, wherein the input bit-stream generator is configured to generate a pulse sequence representing a corresponding input stochastic bit-stream according to respective preset input values in a preset input vector, the weight bit-stream generator is configured to generate a pulse sequence representing a corresponding weight stochastic bit-stream according to respective preset weight values in a preset weight matrix and the pulse sequence representing the input stochastic bit-stream and the pulse sequence representing the weight stochastic bit-stream are applied to a word line and a bit line of the memory array respectively; and,

In addition, he memory array is selected row by row based on a preset time sequence; the pulse sequence representing each input stochastic bit-stream corresponding to respective preset input values in the preset input vector is sequentially applied to each word line of the memory array based on the preset time sequence, and the pulse sequence representing all weight stochastic bit-streams respectively corresponding to all preset weight values in each row of the preset weight matrix are sequentially applied to a corresponding bit line of the memory array based on the preset time sequence, respectively.

In addition, a result multiply-accumulating between the input stochastic bit-stream and the weight stochastic bit-stream of each memory device of the memory array is stored as a conductance value of the corresponding memory device.

In addition, according to a preferred embodiment, in the pulse sequence representing the input stochastic bit-stream, “1” is represented by a positive pulse of V/2, and “0” is represented by a voltage value of 0, and in the pulse sequence representing the weight stochastic bit-stream, “1” is represented by a negative pulse of V/2, and “0” is represented by a voltage value of 0; or,

According to another preferred embodiment, in the pulse sequence representing the input stochastic bit-stream, “1” is represented by a negative pulse of V/2, and “0” is represented by the voltage value of 0, in the pulse sequence representing the weight stochastic bit-stream, “1” is represented by a positive pulse of V/2, and “0” is represented by the voltage value of 0.

In addition, a preferred solution is that: the pulse sequence representing the weight stochastic bit-stream and the pulse sequence representing the input stochastic bit-stream are applied to the top electrodes and the bottom electrodes of the memory device of the memory array, respectively.

In addition, a preferred solution is that: the operation system further includes a read pulse generator and an output extractor.

In addition, the read pulse generator is configured to generate a read pulse, and apply the read pulse to each row of the memory array after the input stochastic bit-stream and the weight stochastic bit-stream of the memory array are applied.

In addition, the output extractor is configured to select the memory array column by column, and obtain a current summation result from each column of the memory array based on Kirchhoff's law as an output of a result multiply-accumulating between the preset input vector and the preset weight matrix.

In addition, according to a preferred embodiment, the memory array is a non-volatile memory array allowing multi-level operations, such as a memristor having a 1T1R structure.

In addition, according to a preferred embodiment, the memory device of the memory array comprises at least one of RRAM, PCM, MRAM, FeRAM, FeFET, or NOR Flash.

In addition, a material of a resistive switching layer of the RRAM includes metal oxide with non-volatile resistive switching characteristics, a material of the resistive switching layer of the PCM includes a phase change material with non-volatile resistive switching characteristics, and a ferroelectric material of the FeRAM and the FeFET includes a doped ferroelectric material or an undoped ferroelectric material.

In another aspect, the present disclosure further provides an operation method of the stochastic matrix-vector multiply-accumulate operation system as described above.

In addition, the operation method includes: generating, by the input bit-stream generator, a pulse sequence representing a corresponding input stochastic bit-stream according to respective preset input values in a preset input vector, and generating, by the weight bit-stream generator, a pulse sequence representing a corresponding weight stochastic bit-stream according to respective preset weight values in a preset weight matrix.

In addition, the operation method includes: select the memory array row by row based on a preset time sequence; sequentially applying the pulse sequence representing each input stochastic bit-stream corresponding to respective preset input values in the preset input vector to each word line of the memory array based on the preset time sequence and sequentially applying the pulse sequence representing all weight stochastic bit-streams respectively corresponding to all preset weight values in each row of the preset weight matrix to a corresponding bit line of the memory array based on the preset time sequence, respectively, so as to store a result multiply-accumulating between each input stochastic bit-stream and corresponding weight stochastic bit-stream as a conductance value of the corresponding memory device.

In addition, the operation method includes: generating a read pulse by the read pulse generator, and applying the read pulse to each row of the memory array after the input stochastic bit-stream and the weight stochastic bit-stream of the memory array are applied.

In addition, the operation method includes: obtaining, by the output extractor, an output of the result multiply-accumulating between the preset input vector and the preset weight matrix from the memory array based on the read pulse.

In addition, according to a preferred to embedment, in the process of generating of the pulse sequence representing the input stochastic bit-stream, “1” is represented by a positive pulse of V/2, and “0” is represented by a voltage value of 0, and in the process of generating of the pulse sequence representing the weight stochastic bit-stream, “1” is represented by a negative pulse of V/2, and “0” is represented by a voltage value of 0.

According to another preferred to embedment, in the process of generating of the pulse sequence representing the input stochastic bit-stream, “1” is represented by a negative pulse of V/2, and “0” is represented by the voltage value of 0, and in the process of generating of the pulse sequence representing the weight stochastic bit-stream, “1” is represented by a positive pulse of V/2, and “0” is represented by the voltage value of 0.

In addition, according to a preferred to embedment, in the process of obtaining, by the output extractor, the output of the result multiply-accumulating between the preset input vector and the preset weight matrix from the memory array based on the read pulse includes selecting, by the output extractor, the memory array column by column, and obtaining a current summation result from each column of the memory array based on Kirchhoff's law as an output of the result multiply-accumulating between the preset input vector and the preset weight matrix.

In addition, according to a preferred embodiment, the pulse sequence representing the weight stochastic bit-stream and the pulse sequence representing the input stochastic bit-stream are applied to the top electrodes and the bottom electrodes of the memory device of the memory array, respectively.

Compared with the prior art, the above-mentioned stochastic matrix-vector multiply-accumulate operation system and the operation method thereof according to the present disclosure have the following beneficial effects.

The stochastic matrix-vector multiply-accumulate operation system and the operation method thereof provided by the present disclosure have the advantage of highly parallel computation compared to the conventional stochastic computing unit circuit based on CMOS, and can improve computing efficiency while reducing hardware area overhead. In addition, compared with the conventional stochastic computing unit based on memory devices, the stochastic matrix-vector multiply-accumulate operation system and the operation method thereof provided by the present disclosure have simple computing operations and a small number of iterations. Meanwhile, the conductivity value of a single device in the array is used to store the result of result multiply-accumulating between two bit-streams and adding bits, which can further reduce the number of devices required and help reduce the array scale.

To achieve the above and related purposes, one or more aspects of the present disclosure include features that will be described in detail later and particularly pointed out in the claims. The following description and the accompanying drawings describe certain exemplary aspects of the present invention in detail. However, these aspects indicate only some of the various ways in which the principles of the present disclosure can be used. In addition, the present disclosure is intended to include all of these aspects and their equivalents.

### BRIEF DESCRIPTION OF DRAWINGS

By referring to the following description and claims in conjunction with the accompanying drawings, and with a more comprehensive understanding of the present disclosure, other objects and results of the present disclosure will become more apparent and easier to understand. In the accompanying drawings:

FIG. 1 is a structural diagram of a stochastic matrix-vector multiply-accumulate operation system during a write operation according to an embodiment of the present disclosure;

FIG. 2 is a structural diagram of a stochastic matrix-vector multiply-accumulate operation system during a read operation according to an embodiment of the present disclosure;

FIG. 3 is a schematic diagram of a bit-stream multiplication of a weight stochastic bit-stream and an input stochastic bit-stream acting on the same memory device in a specific embodiment of the present disclosure;

FIG. 4 is a schematic diagram of implementing multiplication of a corresponding input vector and a weight matrix and addition of some bits in an embodiment of the present disclosure;

FIG. 5 is a schematic diagram of completing the multiply-accumulate operation of the final input vector and the weight matrix through parallel read operations in an embodiment of the present disclosure;

The same reference numbers throughout the drawings indicate similar or corresponding features or functions.

### DETAILED DESCRIPTIONS

In the following description, for purposes of explanation, numerous specific details are set forth in order to provide a thorough understanding of one or more embodiments. It will be apparent, however, that these embodiments may be practiced without these specific details. In other instances, well-known structures and devices are shown in block diagram form in order to facilitate describing one or more embodiments.

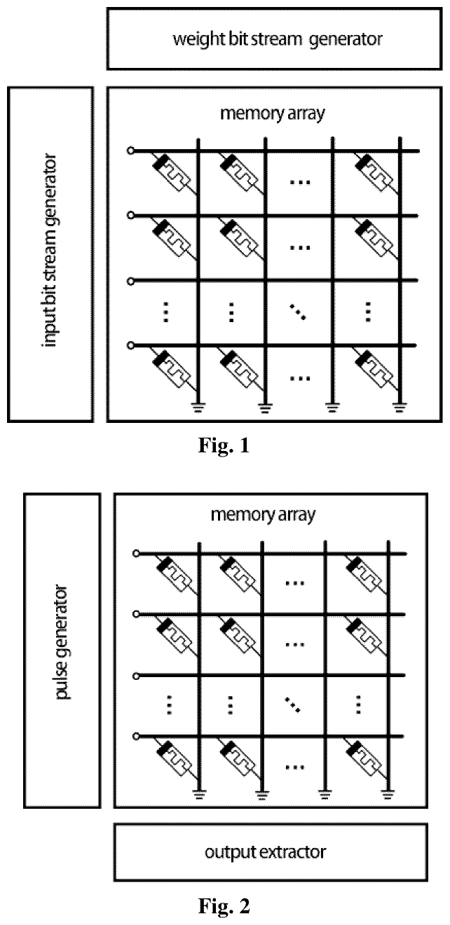

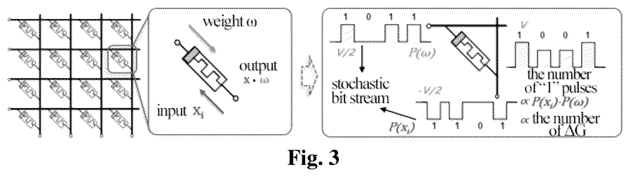

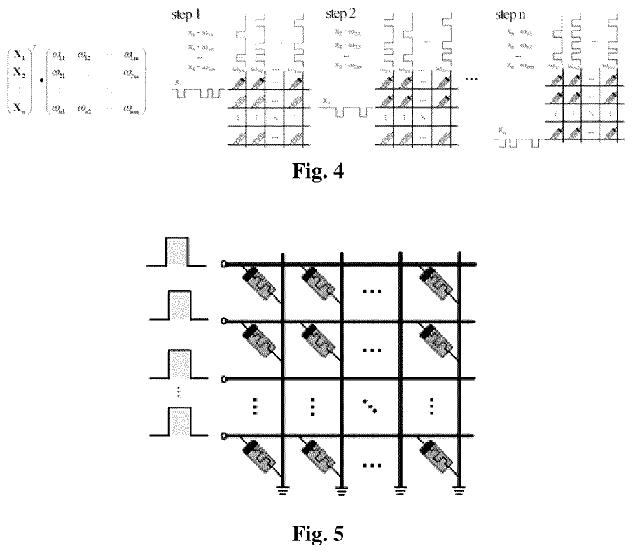

FIG. 1 is a structural diagram of a stochastic matrix-vector multiply-accumulate operation system during a write operation according to an embodiment of the present disclosure; FIG. 2 is a structural diagram of a stochastic matrix-vector multiply-accumulate operation system during a read operation according to an embodiment of the present disclosure; FIG. 3 is a schematic diagram of a bit-stream multiplication of a weight stochastic bit-stream and an input stochastic bit-stream acting on the same memory device in a specific embodiment of the present disclosure; FIG. 4 is a schematic diagram of implementing multiplication of a corresponding input vector and a weight matrix and addition of some bits in an embodiment of the present disclosure; FIG. 5 is a schematic diagram of completing the multiply-accumulate operation of the final input vector and the weight matrix through parallel read operations in an embodiment of the present disclosure.

As shown in FIGS. 1 to 5, the stochastic matrix-vector multiply-accumulate operation system provided in the present disclosure includes an input bit-stream generator for generating a stochastic bit-stream representing a preset input value of a preset input vector, a weight bit-stream generator for generating a stochastic bit-stream representing respective preset weight values of a preset weight matrix, and a memory array for implementing multiply-accumulate operations of the input bit-stream and the weight bit-stream.

Specifically, the input bit-stream generator is configured to generate a pulse sequence representing a corresponding input stochastic bit-stream according to respective preset input values of a preset input vector, and the weight bit-stream generator is configured to generate a pulse sequence representing a corresponding weight stochastic bit-stream according to respective preset weight values of a preset weight matrix. And then, the pulse sequence representing the input stochastic bit-stream and the pulse sequence representing the weight stochastic bit-stream are applied to a word line and a bit line of the memory array respectively (i.e., the pulse sequence representing the input stochastic bit-stream are applied to a word line of the memory array, and the pulse sequence representing the weight stochastic bit-stream are applied to a bit line of the memory array; or the pulse sequence representing the input stochastic bit-stream are applied to a bit line of the memory array and the pulse sequence representing the weight stochastic bit-stream are applied to a word line of the memory array).

It should be noted that, the memory array is selected row by row based on a preset time sequence, the pulse sequence representing each input stochastic bit-stream corresponding to respective preset input values of the preset input vector is sequentially applied to each word line of the memory array based on the preset time sequence and the pulse sequence representing all weight stochastic bit-streams respectively corresponding to all preset weight values in each row of the preset weight matrix are sequentially applied to a corresponding bit line of the memory array based on the preset time sequence, respectively. In addition, the result multiply-accumulating between input stochastic bit-stream and weight stochastic bit-stream of each memory device of the memory array is stored as a conductance value of the corresponding memory device.

Specifically, the stochastic bit-streams representing the weight and the input (i.e., the input stochastic bit-stream and the weight stochastic bit-stream) are respectively encoded into the form of voltage pulses through the input bit-stream generator and the weight bit-stream generator, wherein the “1” bits in the weight stochastic bit-stream are represented by a positive (negative) voltage pulse, and the “0” bits are represented by a voltage pulse of 0 voltage level, whereas the “1” bits in the stochastic bit-stream representing the input are represented by a negative (positive) voltage pulse, and the “0” bits are represented by a voltage pulse of 0 voltage level. In addition, a positive and negative of voltage pulses representing the “1” bits of the weight stochastic bit-stream need to be opposite to positive and negative of the voltage pulse representing the “1” bits of the input stochastic bit-stream. For example, in the pulse sequence representing the input stochastic bit-stream, “1” is represented by a positive pulse of V/2, and “0” is represented by a voltage value of 0, and in the pulse sequence representing the weight stochastic bit-stream, “1” is represented by a negative pulse of V/2, and “0” is represented by a voltage value of 0. Or, in the pulse sequence representing the input stochastic bit-stream, “1” is represented by a negative pulse of V/2, and “0” is represented by a voltage value of 0, and in the pulse sequence representing the weight stochastic bit-stream, “1” is represented by a positive pulse of V/2, and “0” is represented by a voltage value of 0.

In the actual pulse applying process, as shown in FIG. 3, the pulse sequence representing the input stochastic bit-stream and the pulse sequence representing the weight stochastic bit-stream are respectively applied to the word line and bit line of the memory array, and each memory device of the memory array is initially in a high impedance state. The array is selected row by row, and only when the pulse sequence representing the input stochastic bit-stream and the pulse sequence representing the weight stochastic bit-stream acting on the same device are both “1” bits, is the positive voltage pulse of which the corresponding pulse amplitude is V output. When the pulse sequence representing the input stochastic bit-stream representing the input is “1” bit (“0” bit), and the pulse sequence representing the weight stochastic bit-stream representing the weight is “0” bit (“1” bit), a positive voltage pulse with a corresponding pulse amplitude of V/2 is output. When the pulse sequences representing the input and weight are both “0” bits, the output corresponds to a voltage value of 0. It should be noted that, due to the multi-value, long-term enhancement and non-volatile characteristics of the memory device, when the output is a positive voltage pulse with a pulse amplitude of V, the conductance of the device will increase by A G, and when the output is a positive voltage pulse with a pulse amplitude of V/2 or a voltage value of 0, the conductance of the device remains unchanged. Based on this, the pulse sequence representing the weight stochastic bit-stream representing the weight is input into the memory array word line (bit line), and the pulse sequence representing the input stochastic bit-stream representing the input is input into the memory array bit line (word line). The array is selected row by row to complete the computing of the corresponding input and weight. After the two bit-streams are multiplied and the bit-by-bit addition is performed, the result will be directly stored as the conductance value of the single device, which can be obtained through a read operation later.

Further, taking one of the memory devices (or memory devices) as an example, at a certain moment in the preset time sequence, the preset weight value and the preset input value are respectively represented by a stochastic bit-stream with a length of 4. Then the stochastic bit-stream representing the preset weight value can be 1011 (value 3/4), where a “1” is represented by a positive pulse of V/2, and a “0” is represented by a voltage value of 0. The stochastic bit-stream representing the preset input value can be 1101 (value is 3/4), wherein “1” is represented by a negative pulse-V/2, and “0” is represented by a voltage value of 0. Pulse sequences representing weight and input stochastic bit-streams are applied to the top and bottom electrodes of the memory device, respectively. After pulse superposition, the output pulse sequence is 1001, wherein “1” is represented by the positive pulse V, and 0 is represented by the positive pulse of V/2. The conductance of the device will not be changed under a voltage pulse of V/2, but the conductance will be changed by ΔG under a voltage pulse of V. The number of “1”s in the output sequence is proportional to the number of ΔG. Since the device is a non-volatile memory array allowing multi-level operations, the result of multiplying the two bits streams and adding the bits is stored as the conductance value of a single memory device, thereby realizing the multiplication operation of a certain preset weight value and the corresponding preset input value.

Furthermore, as shown in FIG. 4, for example, during the multiply-accumulate computing of an n-dimensional input row vector and an n×m-dimensional weight matrix, the memory array is selected one row at a time to complete the computing of the corresponding input and the weight in one row of the weight matrix, and the result of multiplying the input and the weight and adding the bits is stored as the conductance value of the corresponding memory device. The array is selected row by row until the computing of the last input Xₙ of the n-dimensional input row vector and the last row of the weight matrix is completed.

In addition, in order to read out the operation results stored as the conductance values of the memory devices of the memory array from the memory array, the stochastic matrix-vector multiply-accumulate operation system provided by the present disclosure may also include a read pulse generator and an output extractor; wherein: the read pulse generator is configured to generate a read pulse, and apply the read pulse to each row of the memory array after the input stochastic bit-stream and the weight stochastic bit-stream of the memory array are applied; and the output extractor is configured to select the memory array column by column, and obtain a current summation result from each column of the memory array based on Kirchhoff's law as an output of a result multiply-accumulating between the preset input vector and the preset weight matrix.

It should be noted that the memory array provided by the present disclosure needs to use a memory array is a non-volatile memory array allowing multi-level operations. For example, the memory devices of the memory array may include at least one of RRAM, PCM, MRAM, FeRAM, FeFET, or NOR Flash. The memory device can adjust the conductance of the device through voltage pulses, and the conductance value of the device gradually changes as the number of voltage pulses increases, or directly use a memristor array having a 1T1R structure where the current limiting of the memristor is controlled by adjusting the gate voltage of the transistor to adjust the conductance of the resistive random-access memory.

Furthermore, the resistive switching layer of the RRAM device of the memory array of the present disclosure can be made of metal oxide with non-volatile resistive switching properties, such as HfO₂, TaOₓ, etc. The resistive switching layer of the PCM can be made of phase change material with non-volatile resistive switching properties, such as GeSe, etc. The ferroelectric materials in the FeRAM and the FeFET can use various HfO₂-doped ferroelectric materials such as HfO₂-doped Zr (HZO), HfO₂-doped Al (HfAlO), etc. Perovskite type ferroelectrics (PZT, BFO, SBT), ferroelectric polymers (P(VDF-TrFE)) or other traditional ferroelectric materials can also be used as ferroelectric materials. The device gate stack can be based on various structures such as MFMIS, MFIS, MFS and so on. The present disclosure aims to propose a system and method that utilizes the non-volatile, programmable, and multi-valued characteristics of a memory device to implement matrix-vector multiply-accumulate operations in stochastic computing. The use of other memory arrays with the above characteristics or memory arrays with other structures are all within the scope of the present disclosure.

On the other hand, in order to further explain the operation principle of the stochastic matrix-vector multiply-accumulate operation system provided by the present disclosure, the present disclosure also provides an operation method of the stochastic matrix-vector multiply-accumulate operation system as mentioned above. The operation method includes the following processes.

Generating, by the input bit-stream generator, a pulse sequence representing a corresponding input stochastic bit-stream according to respective preset input values of a preset input vector, and generating, by the weight bit-stream generator, a pulse sequence representing a corresponding weight stochastic bit-stream according to respective preset weight values of a preset weight matrix.

In addition, the method includes: selecting the memory array row by row based on a preset time sequence; sequentially applying the pulse sequence representing each input stochastic bit-stream corresponding to respective preset input values of the preset input vector to each word line of the memory array based on the preset time sequence and sequentially applying the pulse sequence representing all weight stochastic bit-streams respectively corresponding to all preset weight values in each row of the preset weight matrix to a corresponding bit line of the memory array based on the preset time sequence, respectively, so as to store a result multiply-accumulating between each input stochastic bit-stream and corresponding weight stochastic bit-stream as a conductance value of the corresponding memory device.

In addition, the method includes: generating a read pulse by the read pulse generator, and applying the read pulse to each row of the memory array after the input stochastic bit-stream and the weight stochastic bit-stream of the memory array are applied;

In addition, the method includes: obtaining, by the output extractor, an output of the result multiply-accumulating between the preset input vector and the preset weight matrix from the memory array based on the read pulse.

In addition, according to a preferred embodiment, in the process of generating of the pulse sequence representing the input stochastic bit-stream, “1” is represented by a positive pulse of V/2, and “0” is represented by a voltage value of 0, and in the process of generating of the pulse sequence representing the weight stochastic bit-stream, “1” is represented by a negative pulse of V/2, and “0” is represented by a voltage value of 0.

According to another preferred embodiment, in the process of generating of the pulse sequence representing the input stochastic bit-stream, “1” is represented by a negative pulse of V/2, and “0” is represented by the voltage value of 0, and in the process of generating of the pulse sequence representing the weight stochastic bit-stream, “1” is represented by a positive pulse of V/2, and “0” is represented by a voltage value of 0.

In addition, according to a preferred embodiment, in the process of obtaining, by the output extractor, the output of the result multiply-accumulating between the preset input vector and the preset weight matrix from the memory array based on the read pulse includes: selecting, by the output extractor, the memory array column by column, and obtaining a current summation result from each column of the memory array based on Kirchhoff's law as an output of the result multiply-accumulating between the preset input vector and the preset weight matrix.

In addition, according to a preferred embodiment, the pulse sequence representing the weight stochastic bit-stream and the pulse sequence representing the input stochastic bit-stream are applied to the top electrodes and the bottom electrodes of the memory device of the memory array, respectively.

The stochastic matrix-vector multiply-accumulate operation system and the operation method thereof provided by the present disclosure have the advantage of highly parallel computation compared to the conventional stochastic computing unit circuit based on CMOS, and can improve computing efficiency while reducing hardware area overhead. In addition, compared with the conventional stochastic computing unit based on memory devices, the stochastic matrix-vector multiply-accumulate operation system and the operation method thereof provided by the present disclosure have simple computing operations and a small number of iterations. Meanwhile, the conductivity value of a single device in the array is used to store the result of multiplying two bits streams and adding bits, which can further reduce the number of memory devices required and help reduce the array scale.

As described above, the stochastic matrix-vector multiply-accumulate operation system and the operation method thereof according to the present disclosure are described by way of example with reference to FIGS. 1 to 5. However, it should be understood by those skilled in the art that various improvements can be made to the stochastic matrix-vector multiply-accumulate operation system and the operation method thereof proposed in the present disclosure without departing from the content of the present disclosure. Therefore, the protection scope of the present disclosure should be determined by the content of the appended claims.

1. A stochastic matrix-vector multiply-accumulate operation system, comprising an input bit-stream generator, a weight bit-stream generator and a memory array,
wherein the input bit-stream generator is configured to generate a pulse sequence representing a corresponding input stochastic bit-stream according to respective preset input values of a preset input vector, the weight bit-stream generator is configured to generate a pulse sequence representing a corresponding weight stochastic bit-stream according to respective preset weight values of a preset weight matrix, and the pulse sequence representing the input stochastic bit-stream and the pulse sequence representing the weight stochastic bit-stream are applied to a word line and a bit line of the memory array, respectively,
wherein the memory array is selected row by row based on a preset time sequence, the pulse sequence representing each input stochastic bit-stream corresponding to respective preset input values of the preset input vector is sequentially applied to each word line of the memory array based on the preset time sequence, and the pulse sequence representing all weight stochastic bit-streams respectively corresponding to all preset weight values in each row of the preset weight matrix are sequentially applied to a corresponding bit line of the memory array based on the preset time sequence, respectively, and
wherein a result multiply-accumulating between the input stochastic bit-stream and the weight stochastic bit-stream of each memory device of the memory array is stored as a conductance value of the corresponding memory device.

2. The stochastic matrix-vector multiply-accumulate operation system according to claim 1, wherein in the pulse sequence representing the input stochastic bit-stream, “1” is represented by a positive pulse of V/2, and “0” is represented by a voltage value of 0, and in the pulse sequence representing the weight stochastic bit-stream, “1” is represented by a negative pulse of V/2, and “0” is represented by a voltage value of 0, or
wherein in the pulse sequence representing the input stochastic bit-stream, “1” is represented by a negative pulse of V/2, and “0” is represented by the voltage value of 0, and in the pulse sequence representing the weight stochastic bit-stream, “1” is represented by a positive pulse of V/2, and “0” is represented by the voltage value of 0.

3. The stochastic matrix-vector multiply-accumulate operation system according to claim 2, wherein the pulse sequence representing the weight stochastic bit-stream and the pulse sequence representing the input stochastic bit-stream are applied to top electrodes and bottom electrodes of the memory devices of the memory array, respectively.

4. The stochastic matrix-vector multiply-accumulate operation system according to claim 3, further comprising a read pulse generator and an output extractor,
wherein the read pulse generator is configured to generate a read pulse, and apply the read pulse to each row of the memory array after the input stochastic bit-stream and the weight stochastic bit-stream of the memory array are applied, and
wherein the output extractor is configured to select the memory array column by column, and obtain a current summation result from each column of the memory array based on Kirchhoff's law as an output of a result multiply-accumulating between the preset input vector and the preset weight matrix.

5. The stochastic matrix-vector multiply-accumulate operation system according to claim 1, wherein the memory array is a non-volatile memory array allowing multi-level variable operations.

6. The stochastic matrix-vector multiply-accumulate operation system according to claim 5, wherein the memory device of the memory array comprises at least one of RRAM, PCM, MRAM, FeRAM, FeFET, or NOR Flash, and
wherein a material of a resistive switching layer of the RRAM comprising a metal oxide with a non-volatile resistive switching characteristic, a material of the resistive switching layer of the PCM comprising a phase change material with a non-volatile resistive switching characteristic, and ferroelectric material of the FeRAM and the FeFET is a doped ferroelectric material or an undoped ferroelectric material.

7. An operation method of the stochastic matrix-vector multiply-accumulate operation system according to claim 1, comprising:
generating, by the input bit-stream generator, the pulse sequence representing the corresponding input stochastic bit-stream according to respective preset input values of the preset input vector, and generating, by the weight bit-stream generator, a pulse sequence representing the corresponding weight stochastic bit-stream according to respective preset weight values of the preset weight matrix;
selecting the memory array row by row based on the preset time sequence; sequentially applying the pulse sequence representing each input stochastic bit-stream corresponding to respective preset input values of the preset input vector to each word line of the memory array based on the preset time sequence, and sequentially applying the pulse sequence representing all weight stochastic bit-streams respectively corresponding to all preset weight values in each row of the preset weight matrix to a corresponding bit line of the memory array based on the preset time sequence, respectively, so as to store the result multiply-accumulating between each input stochastic bit-stream and corresponding weight stochastic bit-stream as the conductance value of the corresponding memory device;
generating a read pulse by the read pulse generator, and applying the read pulse to each row of the memory array after the input stochastic bit-stream and the weight stochastic bit-stream of the memory array are applied; and
obtaining, by the output extractor, an output of the result multiply-accumulating between the preset input vector and the preset weight matrix from the memory array based on the read pulse.

8. The operation method of the stochastic matrix-vector multiply-accumulate operation system according to claim 7, wherein in the process of generating of the pulse sequence representing the input stochastic bit-stream, “1” is represented by a positive pulse of V/2, and “0” is represented by a voltage value of 0, and in the process of generating of the pulse sequence representing the weight stochastic bit-stream, “1” is represented by a negative pulse of V/2, and “0” is represented by a voltage value of 0, or
wherein in the process of generating of the pulse sequence representing the input stochastic bit-stream, “1” is represented by a negative pulse of V/2, and “0” is represented by the voltage value of 0, and in the process of generating of the pulse sequence representing the weight stochastic bit-stream, “1” is represented by a positive pulse of V/2, and “0” is represented by the voltage value of 0.

9. The operation method of the stochastic matrix-vector multiply-accumulate operation system according to claim 8, wherein the process of obtaining, by the output extractor, the output of the result multiply-accumulating between the preset input vector and the preset weight matrix from the memory array based on the read pulse comprises: selecting, by the output extractor, the memory array column by column, and obtaining a current summation result from each column of the memory array based on Kirchhoff's law as an output of the result multiply-accumulating between the preset input vector and the preset weight matrix.

10. The operation method of the stochastic matrix-vector multiply-accumulate operation system according to claim 9, wherein the pulse sequence representing the weight stochastic bit-stream and the pulse sequence representing the input stochastic bit-stream are applied to top electrodes and bottom electrodes of the memory devices of the memory array, respectively.
